(19) United States
(12) Patent Application Publication
(10) Pub. No.: US 2005/0103273 A1
(43) Pub. Date: May 19, 2005

(54) Vacuum evaporation crucible and phosphor sheet manufacturing apparatus using the same

(75) Inventors: Yukihisa Noguchi, Kanagawa (JP); Makoto Kashiwaya, Kanagawa (JP); Juniji Nakada, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/943,144

(22) Filed: Sep. 17, 2004

(30) Foreign Application Priority Data
Sep. 18, 2003 (JP) 2003-325704

(51) Int. Cl. C23C 16/00

(52) U.S. Cl. 118/726

(57) ABSTRACT

A crucible for vacuum evaporation includes a crucible main body accommodating a film forming material and generating heat through energization and a convection member secured in position inside the crucible main body and forcibly changing the direction of natural convection of the molten material. Other crucible includes the crucible main body and a cover member closing the material accommodating portion of the main body and equipped with a vapor outlet port, the main body and the cover member being firmly connected to each other. A phosphor sheet manufacturing apparatus uses those crucibles.

### BACKGROUND OF THE INVENTION

The present invention relates to a vacuum evaporation crucible for vacuum evaporation using resistance heating. In particular, the present invention relates to a vacuum evaporation crucible utilizing resistance heating that is most suitable for forming a phosphor layer and to a phosphor sheet manufacturing apparatus using this vacuum evaporation crucible.

There are known a class of phosphors which accumulate a portion of applied radiations (e.g. x-rays, α-rays, β-rays, γ-rays, electron beams, and uv (ultraviolet) radiation) and which, upon stimulation by exciting light such as visible light, give off a burst of light emission in proportion to the accumulated energy. Such phosphors called stimulable phosphors are employed in medical and various other applications.

An exemplary application is a radiation image information recording and reproducing system which employs a sheet having a layer formed of the stimulable phosphor. The layer is hereunder referred to as the phosphor layer and the sheet is hereunder referred to simply as a phosphor sheet or sometimes as a radiation image converting sheet. This radiation image information recording and reproducing system has already been commercialized as FCR (Fuji Computed Radiography).

In that system, radiation image information about the subject such as the human body is recorded on the phosphor sheet (more specifically, the phosphor layer). After the radiation image information is thus recorded, the phosphor sheet is scanned two-dimensionally with exciting light such as laser light to produce stimulated emission which, in turn, is read photoelectrically to yield an image signal. Then, an image reproduced on the basis of the read image signal is output as the radiation image of the subject, typically to a display device such as CRT or on a recording material such as a photographic material.

The phosphor sheet is typically produced by the steps of first preparing a coating solution having the particles of a stimulable phosphor dispersed in a solvent containing a binder, etc., applying the coating solution to a support in sheet form that is made of glass or resin, and drying the applied coating.

Phosphor sheets are also known that are made by forming a phosphor layer on a support through methods of physical vapor deposition (vapor-phase film formation) such as vacuum evaporation, as disclosed in JP 2789194 B and JP 5-249299 A). The phosphor layer prepared by evaporation has excellent characteristics. First, it contains less impurities since it is formed under vacuum; in addition, it is substantially free of any substances other than the stimulable phosphor, as exemplified by the binder, so it has high uniformity in performance and still assures very high luminous efficiency.

As a method of heating a film forming material for a film forming method based on vacuum evaporation, a method based on resistance heating is known, in which the film forming material is accommodated in a crucible formed of a high melting point metal and in which the crucible is energized to generate heat, which heat is utilized to heat the film forming material. Known examples of the configuration of a resistance heating crucible for use in vacuum evaporation include a boat-shaped configuration, a cup-shaped configuration, and a chimney-shaped configuration.

Here, it is to be noted that by resistance heating using a conventional crucible, it is impossible to obtain a phosphor layer of a proper quality in a stable manner.

In a conventional crucible, local heating, etc. of the molten material (the molten film forming material) is likely to occur, so that the crucible is subject to bumping. When bumping occurs, the film forming material adheres to the substrate, and the adhering portion undergoes abnormal growth, resulting in a so-called film defect. Further, as a result of bumping, the characteristic distribution of the phosphor layer becomes uneven.

Further, a conventional crucible involves great fluctuation of the evaporation surface (the liquid surface), so that the evaporation speed is rather unstable, resulting in an uneven characteristic distribution of the phosphor layer.

Apart from this, as a phosphor layer forming method providing a satisfactory stimulated emission characteristic, a multiple source vacuum evaporation film forming method is known, according to which a film forming material constituting the phosphor component (base material) and a film forming material constituting the activator component are evaporated separately and independently of each other.

Here, in the phosphor layer, the amount of activator is very small, so that, in multiple source vacuum evaporation, the amount of film forming material filling the crucible is also small. Thus, when the material leaks to the exterior of the crucible due to bumping or the like, the material utilization efficiency markedly deteriorates. Further, the activator material is mostly expensive, so that material leakage from the crucible leads to a serious problem in terms of cost.

### SUMMARY OF THE INVENTION

It is an object of the present invention to solve the above problems in the prior art. According to a first aspect of the present invention, there is provided a crucible suitable for use in vacuum evaporation based on resistance heating, in particular, a crucible suitable for formation of a stimulable phosphor layer, wherein generation of bumping, fluctuation of the evaporation surface, etc. are substantially suppressed to enable stable formation of a thin film free from film defect and superior in evenness in characteristic distribution. According to a second aspect of the present invention, there is provided a similar crucible for vacuum evaporation which is capable of appropriately preventing liquid leakage to the exterior even if bumping or the like occurs. According to a further aspect of the present invention, there is provided a phosphor sheet manufacturing apparatus using such a crucible according to the present invention as described above, wherein a high quality phosphor layer is formed through vacuum evaporation.

In order to achieve the above object, according to a first aspect of the present invention,there is provided a crucible for vacuum evaporation including: a crucible main body which accommodates a film forming material and generates heat through energization; and a convection member which is secured in position inside said crucible main body and forcibly changes a direction of natural convection of said film forming material that is molten.

In the crucible for vacuum evaporation according to a first aspect of the present invention, it is preferable that said convection member is formed of a material generating the heat through the energization and is electrically connected to said crucible main body. Further, it is preferable that said convection member is arranged in contact with an inner surface of said crucible main body and at a position opposed to an outlet port for a vapor of the film forming material. Further, it is preferable that said convection member is positioned such that said convection member closes an outlet port for a vapor of the film forming material as seen from above when installed in a vacuum evaporation apparatus. Further, it is preferable that said crucible main body has in a part of a hollow container an opening for discharging a vapor of the film forming material that is evaporated, and has a chimney-shaped discharge portion protruding outwardly and surrounding said opening. Furthermore, it is preferable that cesium bromide is accommodated and evaporated as said film forming material.

Further, according to a second aspect of the present invention, there is provided a crucible for vacuum evaporation, including: a crucible main body which accommodates a film forming material and generates heat through energization; and a cover member which closes a film forming material accommodating portion of said crucible main body and is equipped with a vapor outlet port for discharging a vapor of said film forming material that is evaporated, wherein said crucible main body and said cover member are firmly connected to each other.

In the crucible for vacuum evaporation according to the second aspect of the present invention, it is preferable that said vapor outlet port is formed as a slit extending in one direction. Further, it is preferable that europium bromide is accommodated and evaporated as said film forming material.

Further, according to a third aspect of the present invention, there is provided a phosphor sheet manufacturing apparatus for forming a phosphor layer on a substrate by vacuum evaporation, including: a vacuum chamber; a substrate retaining mechanism; and a first crucible for vacuum evaporation including: a first crucible main body which accommodates a film forming material and generates heat through energization; and a convection member which is secured in position inside said first crucible main body and forcibly changes a direction of natural convection of said film forming material that is molten, wherein at least one film forming material for forming said phosphor layer is evaporated through resistance heating using said first crucible for vacuum evaporation.

In the phosphor sheet manufacturing apparatus for forming a phosphor layer on a substrate by vacuum evaporation according to the third aspect of the present invention, it is preferable that said phosphor layer is formed by multiple source vacuum evaporation in which film forming materials for a phosphor component and an activator component are heated and evaporated separately from and independently of each other, said phosphor component being evaporated through the resistance heating using said first crucible for vacuum evaporation. Further, it is preferable to include a second crucible for vacuum evaporation comprising: a second crucible main body which accommodates a film forming material and generates heat through energization, and a cover member which closes a film forming material accommodating portion of said second crucible main body and is equipped with a vapor outlet port for discharging a vapor of said film forming material that is evaporated, wherein said second crucible main body and said cover member are firmly connected to each other, and wherein the film forming material for the activator component is evaporated through the resistance heating using said second crucible for vacuum evaporation. Further, it is preferable that said first crucible accommodates cesium bromide as the film forming material for the phosphor component, and wherein said second crucible accommodates europium bromide as the film forming material for the activator component. Further, it is preferable that said convection member of said first crucible for vacuum evaporation is formed of a material generating the heat through the energization and is electrically connected to said first crucible main body. Further, it is preferable that said convection member of said first crucible for vacuum evaporation is arranged in contact with an inner surface of said first crucible main body and at a position opposed to an outlet port for a vapor of the film forming material. Further, it is preferable that said convection member of said first crucible for vacuum evaporation is positioned such that said convection member closes an outlet port for a vapor of the film forming material as seen from above when installed at a predetermined position. Further, it is preferable that said first crucible main body of said first crucible for vacuum evaporation has in a part of a hollow container an opening for discharging a vapor of the film forming material that is evaporated, and has a chimney-shaped discharge portion protruding outwardly and surrounding said opening. Furthermore, it is preferable that the vapor outlet port of said second crucible for vacuum evaporation is formed as a slit extending in one direction.

In this way, according to the present invention, it is possible to realize a crucible for vacuum evaporation which substantially suppresses generation of bumping of the molten film forming material, fluctuation of the evaporation surface, etc. and which is capable of forming a thin film free from film defect and superior in uniformity in characteristic distribution, and a crucible for vacuum evaporation which is capable of appropriately preventing liquid leakage to the exterior even if bumping of the molten film forming material or the like occurs.

Further, with the phosphor sheet manufacturing apparatus of the present invention, it is possible to manufacture at low cost a high quality phosphor sheet involving very little surface defect by using such a vacuum evaporation crucible according to the present invention having such superior characteristics.

This application claims priority on Japanese patent application No. 2003-325704, the entire contents of which are hereby incorporated by reference. In addition, the entire contents of literatures cited in this specification are incorporated by reference.

### BRIEF DESCRIPTION OF THE DRAWINGS

In the accompanying drawings:

FIG. 1 is a conceptual drawing showing an embodiment of a phosphor sheet manufacturing apparatus utilizing a vacuum evaporation crucible of the present invention;

FIG. 2A is a schematic top view of an embodiment of a vacuum evaporation crucible according to a first aspect of the present invention, FIG. 2B is a schematic front view of the same, FIG. 2C is a schematic side view of the same, and FIG. 2D is a schematic top view of a convection member arranged in the vacuum evaporation crucible;

FIG. 3A is a schematic top view of another embodiment of a vacuum evaporation crucible according to the first aspect of the present invention, FIG. 3B is a schematic front view of the same, and FIG. 3C is a schematic side view of a convection member arranged in the vacuum evaporation crucible;

FIG. 4A is a schematic top view of still another embodiment of a vacuum evaporation crucible according to the first aspect of the present invention, FIG. 4B is a schematic front view of the same, and FIG. 4C is a schematic side view of a convection member arranged in the vacuum evaporation crucible;

FIG. 5A is a schematic top view of yet another embodiment of a vacuum evaporation crucible according to the first aspect of the present invention, FIG. 5B is a schematic front view of the same, FIG. 5C is a schematic side view of a convection member arranged in the vacuum evaporation crucible, and FIG. 5D is a schematic side view of another example of the convection member; and

FIG. 6A is a schematic top view of an embodiment of a vacuum evaporation crucible according to a second aspect of the present invention, FIG. 6B is a schematic front view of the same, FIG. 6C is a schematic top view of a main body of this vacuum evaporation crucible, FIG. 6D is a schematic front view of the main body of this vacuum evaporation crucible, FIG. 6E is a schematic top view of a cover member of this vacuum evaporation crucible, FIG. 6F is a schematic front view of the cover member of this vacuum evaporation crucible, and FIG. 6G is a schematic front view of another example of the cover member of this vacuum evaporation crucible.

### DESCRIPTION OF THE PREFERRED EMBODIMENTS

In the following, preferred embodiments of a vacuum evaporation crucible and a phosphor sheet manufacturing apparatus of the present invention will be described in detail with reference to the accompanying drawings.

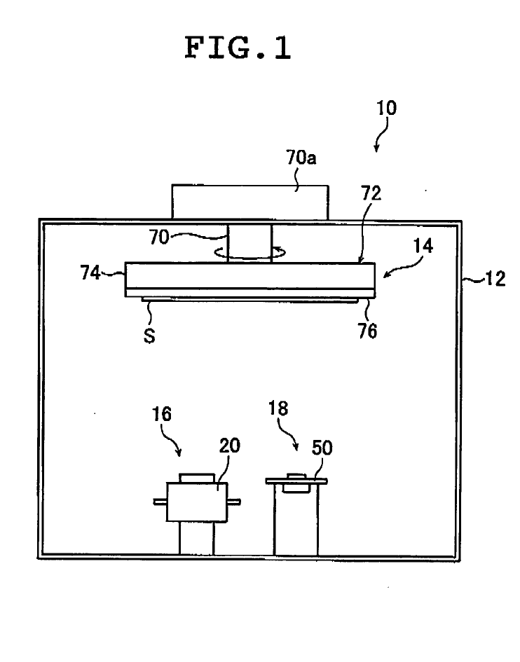

FIG. 1 is a conceptual drawing showing an embodiment of the phosphor sheet manufacturing apparatus of the present invention utilizing the vacuum evaporation crucible of the present invention.

The phosphor sheet manufacturing apparatus 10 shown in FIG. 1 (hereinafter referred to as a manufacturing apparatus) basically includes a vacuum chamber 12, a substrate retaining/rotating mechanism 14, a phosphor evaporating portion 16, and an activator evaporating portion 18. It goes without saying that, apart from this, the manufacturing apparatus 10 of the present invention may include various components with which a well-known vacuum evaporation apparatus is equipped.

The manufacturing apparatus 10 is a two-source vacuum evaporation apparatus, which manufactures a stimulable phosphor sheet by forming on the surface of a substrate S a layer consisting of a stimulable phosphor (hereinafter referred to as the phosphor layer) through two-source vacuum evaporation in which a material constituting the phosphor (base material) and a material constituting the activator are separately evaporated.

In the illustrated case, as a suitable example, a phosphor sheet is prepared by forming a phosphor layer of a stimulable phosphor CsBr:Eu on the substrate S through two-source vacuum deposition by resistance heating using film forming materials including cesium bromide (CsBr) as the phosphor component and europium bromide (EuBrₓ. (where x is generally 2 to 3)) as the activator component.

Note that in the present invention, various materials can be used instead of CsBr:Eu as the stimulable phosphor which is a target for film formation. JP 57-148285 A discloses an example of a preferable alkali halide-based stimulable phosphor represented by the general formula “M^{I}X.aM^{II}X′₂.bM^{III}X″₃:cA”. In this formula, M^{I} represents at least one element selected from the group consisting of Li, Na, K, Rb, and Cs. M^{II} represents at least one divalent metal selected from the group consisting of Be, Mg, Ca, Sr, Ba, Zn, Cd, Cu, and Ni. M^{III} represents at least one trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one element selected from the group consisting of F, Cl, Br, and I. A represents at least one element selected from the group consisting of Eu, Tb, Ce, Tm, Dy, Pr, Ho, Nd, Yb, Er, Gd, Lu, Sm, Y, Tl, Na, Ag, Cu, Bi, and Mg. a satisfies a relationship of 0≦a<0.5, b satisfies a relationship of 0≦b<0.5, and c satisfies a relationship of 0≦c<0.2.

Further, preferable examples of stimulable phosphors other than that described above include those disclosed in U.S. Pat. No. 3,859,527, JP 55-012142 A, JP 55-012144 A, JP 55-012145 A, JP 57-148285 A, JP 56-116777 A, JP 58-069281 A, and JP 59-075200 A.

In particular, the above described alkali halide-based stimulable phosphors are preferred because of photo-stimulated luminescence characteristics, sharpness of reproduced images, the ability to suitably exhibit the effects of the present invention, and the like. Of those, alkali halide-based stimulable phosphors in which M^{I} contains at least Cs, X contains at least Br, and A is Eu or Bi are more preferred. Of those, “CsBr:Eu” is particularly preferred.

Further, the substrate S is not particularly limited and may include all types of substrates used in a phosphor sheet such as glass, ceramics, carbon, aluminium, PET (polyethylene terephthalate), PEN (polyethylene naphthalate), and polyamide.

The vacuum chamber 12 is a well-known vacuum chamber (bell jar or vacuum vessel) used in a vacuum evaporation apparatus and is formed of iron, stainless steel, aluminum, or the like.

A vacuum pump (not shown) is connected to the vacuum chamber 12. There are no particular limitations regarding the vacuum pump, and various types of vacuum pumps as used in vacuum evaporation apparatuses can be used as long as they help to attain the requisite vacuum level. Examples of the vacuum pump that can be used include an oil diffusion pump, a cryo pump, and a turbo molecular pump; further, as an auxiliary component, it is also possible to use a cryo-coil or the like. It is to be noted that in the manufacturing apparatus 10 for forming a phosphor layer, it is desirable for the vacuum degree attained in the vacuum chamber 40 to be 8.0×10⁻⁴ Pa or less.

Further, to perform medium-vacuum film formation described below in a satisfactory manner, it is desirable for the vacuum chamber 12 (the manufacturing apparatus of the present invention) to have a gas introducing means for introducing a gas, such as argon gas or nitrogen gas.

The substrate retaining/rotating mechanism 14 (hereinafter referred to as the rotating mechanism 14) retains a substrate S and rotates at a predetermined speed. The rotating mechanism 14 is composed of a rotation shaft 70 engaged with a rotation drive source 70a, and a turntable 72.

The turntable 72 is a disc composed of a main body 74 on the upper side and a sheathed heater 76 on the lower side (the two evaporating portions side), and the rotation shaft 70 is fixed at the center thereof. The turntable 72 retains the substrate S at a predetermined position on the lower surface (the lower surface of the sheathed heater 76), and is rotated at a predetermined speed by the rotation drive source 70a. The sheathed heater 76 heats the substrate S, on which a phosphor layer is formed, from the back surface side (the surface on the side opposite to the film forming surface), thereby heating the substrate S and the phosphor layer formed.

The substrate S is retained on the turntable 72 by a well-known method using a holder also serving as a mask, a jig, etc., with the film forming surface being directed downwardly.

In the embodiment shown, the rotating mechanism 14 (the turntable 72) rotates while retaining a single substrate S, but this should not be construed restrictively; it is also possible for the rotating mechanism 14 to retain a plurality of substrates S or rotate and revolve the holder retaining the substrate S by using a planetary gear or the like.

In the lower portion of the vacuum chamber 12, there are arranged the phosphor evaporating portion 16 and the activator evaporating portion 18. Further, although not shown, directly above the phosphor evaporating portion 16 and the activator evaporating portion 18, there is arranged a well-known shutter for shielding the vapors of the film forming materials from the two evaporating portions (Such a shutter is provided in various types of vacuum evaporation apparatuses).

As stated above, the manufacturing apparatus 10 shown performs two-source vacuum evaporation using cesium bromide (CsBr) as the film forming material constituting the phosphor component and europium bromide (EuBrₓ (x usually ranges from 2 to 3)) as the film forming material constituting the activator component, thereby forming on the substrate S a phosphor layer consisting of CsBr:Eu. The phosphor evaporating portion 16 heats and evaporates cesium bromide through resistance heating by using a vacuum evaporation crucible according to a first aspect of the present invention (hereinafter referred to as the crucible). The activator evaporating portion 18 heats and evaporates europium bromide through resistance heating by using a vacuum evaporation crucible according to a second aspect of the present invention. The present invention is not restricted to this mode; it is also possible to evaporate the activator component by a crucible according to the first aspect of the present invention and to evaporate the phosphor component by a crucible according to the second aspect of the present invention.

The phosphor evaporating portion 16 includes a crucible 20 constituting the resistance heating evaporation source and a power source (not shown) for resistance heating. The activator evaporating portion 18 includes a crucible 50 constituting the resistance heating evaporation source and a power source (the same as the above) for resistance heating.

In the present invention, there are no particular limitations regarding the power source for resistance heating (heating control means); it is possible to adopt various systems for use in resistance heating devices, such as a thyristor system, a DC system, or a thermocouple feedback system. Further, there are no particular limitations regarding the output when effecting resistance heating; it may be appropriately set according to the film forming materials used, the resistance value of the crucible forming material, the amount of heat generated, etc.

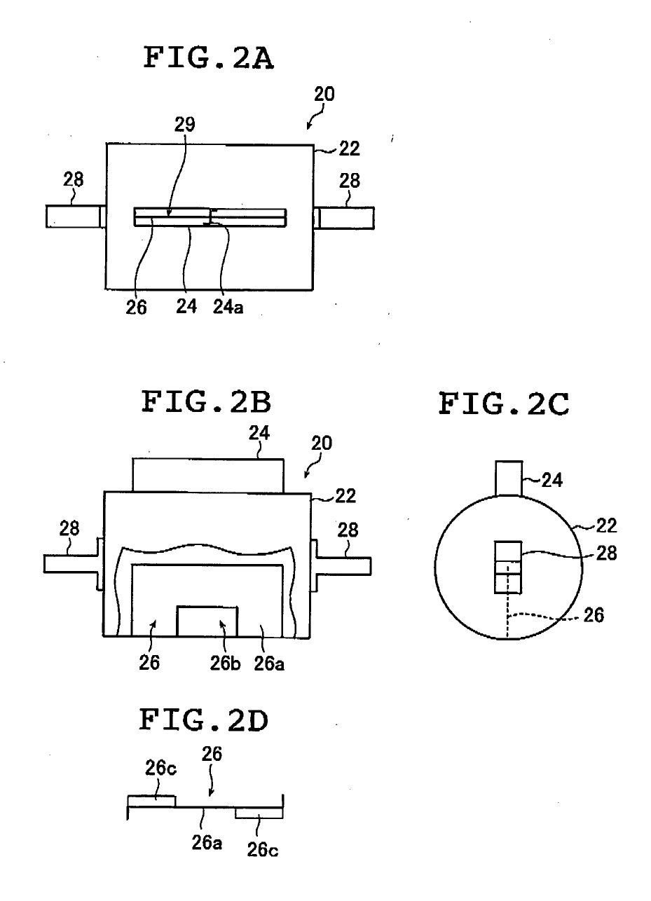

FIGS. 2A through 2D schematically show the crucible 20 arranged in the phosphor evaporating portion 16. FIG. 2A is a top view, FIG. 2B is a partially cutaway front view (as seen from the same direction as in FIG. 1), and FIG. 2C is a side view.

The crucible 20 is an example of the crucible of the first aspect of the present invention, and basically includes a crucible main body 22, a chimney 24, and a convection member 26 arranged in the crucible main body 22.

The crucible main body 22 is to be heated, with its interior being filled with the film forming material (cesium bromide); it is formed as a substantially cylindrical hollow member, and has in its side surface a rectangular opening 29 extending in the axial (center axis) direction. Further, formed on the end surfaces of the crucible main body 22 are electrodes 28 connected to the power source for resistance heating.

The crucible main body 22 is formed of a high melting point metal, such as tantalum (Ta), molybdenum (Mo), or tungsten (W), which is used in a crucible serving as a resistance heating evaporation source in vacuum evaporation. The crucible main body 22 generates beat by being energized through the electrodes 28, evaporating, through heating and melting, the film forming material with which it is filled.

As stated above, in the side surface of the crucible main body 22, there is formed the opening 29 extending in the axial direction of the crucible main body 22 (hereinafter simply referred to as the axial direction). That is, the extending direction of the opening 29 coincides with the energizing direction.

Fixed to the crucible main body 22 is the substantially square-prism-shaped chimney 24 which has a bottom surface with substantially the same configuration as that of the opening 29 and is open on the upper and lower sides, with the chimney surrounding the opening 29. Further, in order to prevent the chimney 24 from being crushed, there is arranged at the center in the axial direction a substantially Z-shaped rib 24a for supporting the chimney 24 from within in the circumferential direction of the crucible main body 22 (the direction perpendicular to the axial direction, that is, the lateral direction of the opening 29, which will be hereinafter referred to as the width direction).

In the crucible 20 shown, the chimney 24 constitutes the outlet port for the vapor of the film forming material and the filling port through which the crucible main body 22 is filled with the film forming material. Thus, basically, the crucible 20 is arranged in the vacuum chamber 12 such that the open end of the chimney 24 is directed vertically upwards.

Due to the presence of the chimney 24, even if bumping occurs in the crucible main body 22, the bumping film forming material is caused to collide with the inner wall of the chimney 24, whereby it is possible to manufacture in a stable manner a high quality phosphor sheet which can appropriately prevent liquid leakage to the exterior and which prevents a deterioration in characteristics due to bumping.

There are no particular limitations regarding the size, etc. of the chimney 24. However, taking into account compatibility between the effect of preventing leakage of the film forming material from the crucible 20 and the satisfactory discharge of the vapor from the crucible 20, it is desirable for the height of the chimney 24 (the protruding length thereof from the crucible main body 22) to range from 10% to 40% of the diameter (when the crucible main body 22 is not cylindrical, the maximum width) of the crucible main body 22. For the same reason, it is desirable for the width of the chimney 24 to range from 4% to 20%.

The crucible of the present invention is not restricted to the above construction with the chimney 24; it is also possible to adopt a construction which has no chimney 24 and in which the vapor of the evaporated film forming material is discharged into the film forming system from the opening 29 of the crucible main body 22.

A convection member 26 is fixed to the inner surface (hereinafter referred to as the bottom surface) which is inside the crucible main body 22 and which is opposed to the chimney 24 (the opening 29).

The convection member 26 is a member for forcibly changing the direction of a convection flow generated naturally in the film forming material melted inside the crucible main body 22. In the example shown, as shown in the top view of FIG. 2D, the convection member 26 has a substantially Z-shaped main body 26a formed by bending at right angles the both longitudinal end portions of a rectangular plate material. This main body 26a has an opening 26b formed by cutting away one lateral end portion thereof into a rectangular shape and, further, mounting portions 26c formed by bending in opposite directions the lateral end portions with the opening 26b therebetween. The mounting portions 26c are formed so as to be of the same curvature as the inner surface of the crucible main body 22. Further, the longitudinal length of the main body 26a of the convection member 26 substantially coincides with the axial length of the chimney 24.

The longitudinal direction of the convection member 26 is matched with the axial direction; by fixing the mounting portions 26c to the bottom surface of the crucible main body 22, the convection member 26 is secured in position inside the crucible main body 22. The fixation of the mounting portions 26c is effected, for example, by EB (electron beam) welding.

Thus, the direction of the convection of the molten film forming material naturally generated inside the crucible main body 22 by heating is forcibly changed by the convection member 26.

As stated above, in the conventional resistance heating crucible for use in vacuum evaporation, due to local heating and temperature distribution of the film forming material, variation in evaporation caused by fluctuation in the liquid surface, etc. there are generated a partial defect due to local film growth, unevenness in phosphor characteristics, etc.

Further, an examination conducted by the present applicant has shown that when performing film formation with the various stimulable phosphors as mentioned above, more specifically, an alkali halide-based stimulable phosphor, and most specifically, through vacuum evaporation with CsBr:Eu, it is desirable to first evacuate the system to a high vacuum degree and then introduce argon gas, nitrogen gas, or the like into the system, performing film formation at a vacuum degree of approximately 0.1 Pa to 2 Pa, in particular, 0.5 Pa to 1.0 Pa (hereinafter referred to, for the sake of convenience, as medium vacuum degree). Here, in vacuum evaporation at this level of vacuum degree, to cause the evaporated film forming material to reliably reach the substrate S, it is necessary for the distance between the film forming material evaporating position and the substrate S to be shorter than usual. In such a film forming system, in which the distance between the evaporating position and the substrate S is short, the problem attributable to bumping of the film forming materials, unevenness in evaporation, etc., is more likely to occur.

In contrast, the crucible of the first aspect of the present invention has the convection member 26 as described above, whereby the direction of the convection of the film forming materials naturally generated according to the configuration and heating condition of the crucible 22 is forcibly changed, and, inside the crucible main body 22, the molten film forming materials are suitably mixed with each other, thus preventing generation of local heating and a large temperature distribution, great fluctuation of the liquid surface, and making it possible to generally uniformalize the heating condition, the melting condition, the temperature, etc. of the film forming materials.

As a result, generation of bumping in the crucible 22, uneven evaporation of the film forming materials due to the temperature distribution inside the crucible, etc. are prevented, making it possible to form a high quality phosphor layer which is relatively free from defects and whose overall characteristic is uniform. Further, due to the reduction in defects, etc., it is possible to attain an improvement in terms of production yield and to achieve a reduction in the production cost of the phosphor sheet.

There are no particular limitations regarding the material of the convection member 26; it is possible to adopt various materials, such as ceramic materials, as long as they exhibit a sufficient heat resistance in conformity with the film forming materials used.

Preferably, the convection member 26 is formed of the same material as the crucible main body 22, and the convection member 26 and the crucible main body 22 are kept electrically connected to each other, whereby it is possible to heat the film forming materials not only with the crucible main body 22 but also with the convection member 26. As a result, the heating efficiency for the film forming materials is improved, and the film forming materials in the crucible main body 22 can be uniformalized more suitably. It is to be noted that the convection member may be formed of a different material allowing resistance heating as long as it can be fixed to the crucible main body 22. This also applies to the other convection members described below.

In the present invention, the configuration and the arrangement position of the convection member 26 are not restricted to those of the embodiment shown in FIGS. 2A through 20; it is possible to utilize various constructions and configurations as long as they help to forcibly change the convection of the molten film forming materials naturally generated in the crucible main body 22.

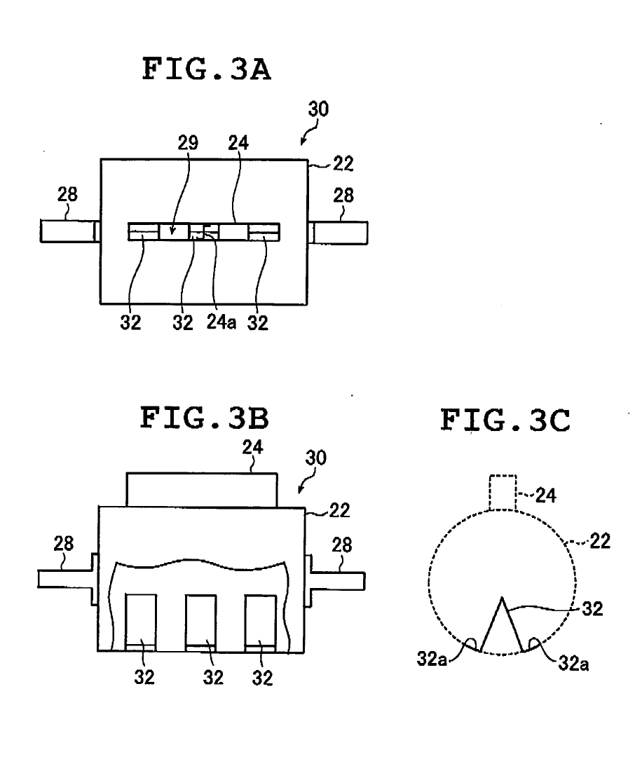

FIGS. 3A through 3C show another embodiment of the crucible of the first aspect of the present invention. FIG. 3A is a top view, FIG. 3B is a front view, and FIG. 3C is a side view of a convection member arranged inside the crucible main body.

In a crucible 30 shown in FIGS. 3A through 3C, there are used, instead of the convection member 26 of the crucible 20 shown in FIGS. 2A through 2D, convection members 32 arranged at three positions. The crucible 30 shown in FIGS. 3A through 3C have the same construction as the crucible 20 shown in FIGS. 2A through 2D except for the convection member. Thus, the components that are the same as those of the above-described embodiment are indicated by the same symbols, and the following description will be centered on the convection member 32 (which also applies to the other embodiments described below).

Each convection member 32 of the crucible 30 is formed by bending an elongated rectangular plate material at an acute angle at its longitudinal center into a substantially V-shape, and by bending the end portions of the V-shaped material outwardly, substantially at right angles to thereby form fixing portions 32a. As in the above embodiment, the fixing portions 32a are formed so as to exhibit the same curvature as the inner surface of the crucible main body 22.

In the crucible 30, the fixing portions 32a of each convection member 32 are fixed to the bottom surface of the crucible main body 22 such that the opening direction of the V-shape and the width direction (the circumferential direction of the crucible main body 22) coincide with each other and that, as seen from above, the center of the open end (the bending line) and the axis of the crucible main body 22 coincide with each other. The fixation of the fixing portions 32a is effected, for example, by EB welding.

In the embodiment shown, three convection members 32 are arranged in the axial direction. The convection members 32 at either end are arranged such that their outer axial ends coincide with the ends of the chimney 24, and the central convection member 32 is arranged such that its center coincides with the center of the chimney 24.

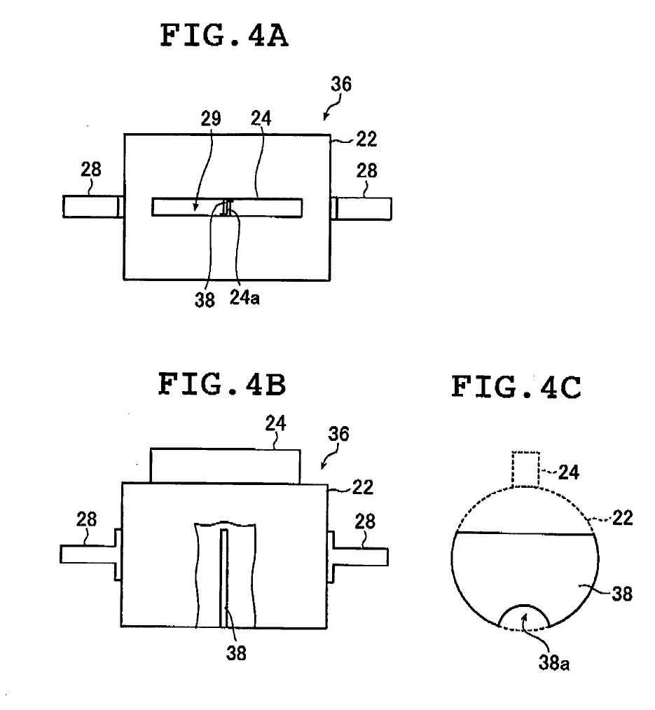

FIGS. 4A through 4C show still another embodiment of the crucible of the first aspect of the present invention. FIG. 4A is a top view, FIG. 4B is a front view, and FIG. 4C is a side view of a convection member arranged inside the crucible main body.

A convection member 38 of the crucible 36 shown in FIGS. 4A through 4C is formed as a substantially bow-shaped plate (a configuration obtained by cutting a circle by a straight line), and has around its arc a depth portion for fixing formed, for example, by drawing. Further, as shown in FIG. 4C, an opening 38a is formed by cutting into a circular shape around the position which is the intersection point of the normal from the center of the chord (the cutting line of the circle) and the arc.

The convection member 38 is arranged at the axial center of the crucible main body 22 such that the opening 38a is directed toward the bottom surface of the crucible main body 22, with the above-mentioned depth portion being in contact with the inner surface of the crucible main body 22 and the bow-shaped surface coinciding with the width direction (that is, the surface is orthogonal to the axial direction), with the depth portion being fixed to the inner surface of the crucible main body 22. The fixation is effected, for example, by EB welding.

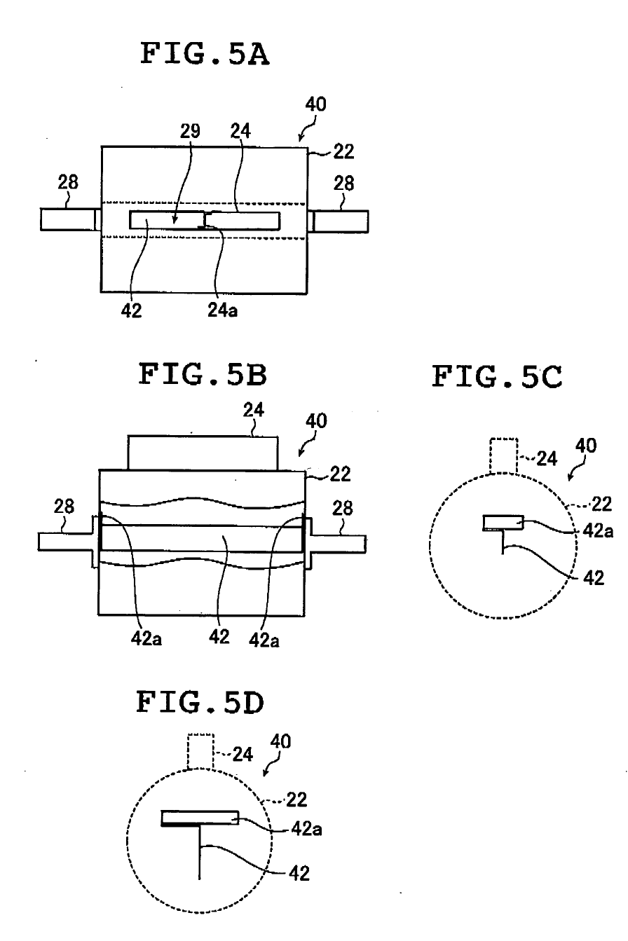

FIGS. 5A through 5C show yet another embodiment of the crucible of the first aspect of the present invention. FIG. 5A is a top view, FIG. 5B is a front view, and FIG. 5C is a side view of a convection member arranged inside the crucible main body.

In the embodiments shown in FIGS. 2A through 4C, the convection member is arranged on the portion of the inner surface of the crucible main body 22 opposed to the outlet port for the vapor of the film forming materials, that is, in contact with the bottom surface and/or the surface portion near the bottom surface of the crucible main body 22. Thus, each of these convection members is constantly in contact with the film forming materials with which the crucible main body 22 is filled. Thus, the convection member greatly contributes to enhancement of the mixing efficiency of the molten film forming materials due to convection and the heating of the film forming materials.

In contrast, in the embodiment shown in FIG. 5, the convection member is arranged such that, when seen from above, it closes the chimney 24. While in this embodiment contribution to the convection and heating of the film forming materials is smaller as compared with that in the above embodiments, it helps to shield the molten film forming materials and any abnormal vaporized substance when the film forming materials undergo bumping, preventing them from leaking to the exterior.

A convection member 42 of the crucible 40 shown in FIGS. 5A through 5D is formed by folding back an elongated rectangular plate material in the lateral direction to thereby obtain a substantially T-shaped configuration. In the convection member 42, the longitudinal end portions in the upper portion of the T-shape are folded back perpendicularly upwards to thereby form mounting portions 42a. Further, the lateral length of the upper portion of the T-shape of the convection member 42 is somewhat larger than the width of the chimney 24, and the longitudinal length of the convection member 42 is the same as the axial length of the inner surface of the crucible main body 22.

In the crucible 40, the convection member 42 is arranged such that its longitudinal direction coincides with the axial direction, that, as seen from above, the upper portion of the T-shaped portion closes the chimney 24, with the T-shaped portion being upright in the same direction as the chimney 24, and that the leg portion of the T-shaped portion passes the axis of the crucible main body 22, with its lower end being positioned somewhat lower than the axis, thus fixing the mounting portions 42a to the inner end surfaces of the crucible main body 22. The fixation is effected, for example, by EB welding. Thus, even when the film forming materials undergo bumping, any abnormal vaporized substance and the molten film forming materials can be suitably shielded by the upper portion of the T-shaped portion, thus preventing them from leaking to the exterior.

In the above-described crucibles, the sizes of the convection members are not restricted to those of the embodiments shown; for example, as in the case of the substantially T-shaped convection member shown in FIG. 5D, the size of the convection member may be increased or reduced compared with the illustrated example as needed.

The number of convection members is not restricted to that of the above embodiments; for example, in the crucible 36 shown in FIGS. 4A through 4C, it is possible to arrange a plurality of convection members 38 in the axial direction, thus allowing various modifications of the construction.

In the crucible of the present invention, the kind of convection member arranged in the crucible main body 22 is not restricted to a single kind. It is also desirable to appropriately combine convection members of different configurations and effects and arrange them in a single crucible main body 22. For example, it is possible to arrange the convection member 32 shown in FIGS. 3A through 3C and the convection member 42 shown in FIGS. 5A through 5D in the crucible main body 22, thereby obtaining a crucible having both the function to enhance the mixing efficiency through convection and the function to shield abnormal vaporized substance due to bumping.

Further, while in all the embodiments described above the convection member is formed by working on a plate material (flat plate), this should not be construed restrictively; for example, it is also possible to form the convection member of a mesh-like material in which line materials are arranged in a lattice-like fashion. In this case also, it is desirable for the convection member to be formed of a material adapted to generate heat through energization as in the case of the material of the crucible main body 22.

While in the above embodiments the crucible (the crucible main body 22) has a cylindrical configuration, this should not be construed restrictively; it may also be of a square-prism-like (tubular) configuration, etc. However, in terms of the workability, strength, evenness in heating, etc., the cylindrical configuration is advantageous.

Further, while in the above preferred embodiments an opening is formed in the cylindrical main body and the chimney (the chimney-like discharge portion) is arranged thereon, the first aspect of the present invention is not restricted thereto. For example, it is also possible to use an ordinary boat-shaped crucible or a rectangular casing with one side open as the crucible main body, and to provide therein a convection member for forcibly changing the direction of the natural convection of the molten film forming materials as in the embodiments described above.

As stated above, the activator evaporating portion 18 is a portion where europium bromide constituting the activator component is heated and evaporated by resistance heating, and has a crucible 50 serving as the resistance heating evaporation source and a resistance heating power source (not shown).

It is to be noted that, in the phosphor layer formed on the phosphor sheet, the activator and the phosphor are in a proportion, for example, of approximately 0.0005/1 to 0.01/1 in molar concentration, which means most of the phosphor layer consists of phosphor. Accordingly, the crucible 50 constituting the activator evaporating portion 18 may be substantially smaller as compared with the above-described phosphor evaporating portion 16.

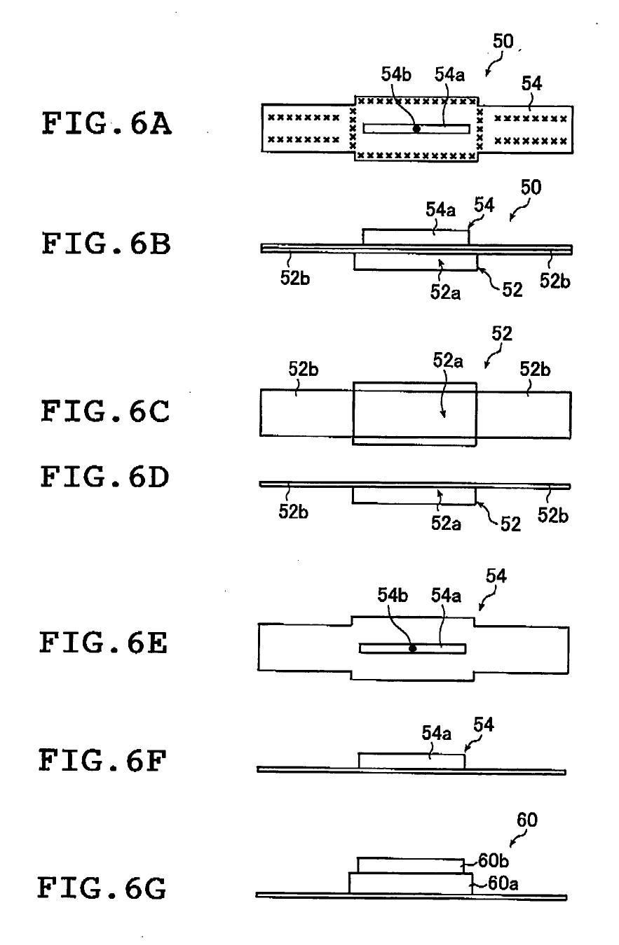

FIGS. 6A through 6G schematically show a crucible 50. FIG. 6A is a top view, and FIG. 6B is a front view.

The crucible 50 of the activator evaporating portion 18 is a crucible according to the second aspect of the present invention, and basically includes a crucible main body 52 and a cover member 54.

FIG. 6C is a top view of the crucible main body 52, and FIG. 6D is a front view thereof. As shown in the drawings, the crucible main body 52 comprises a substantially rectangular parallelepiped-shaped hollow recess 52a with its upper side open and resistance heating electrodes 52b formed integrally with the recess 52a and situated longitudinally on either side of the recess 52a. The recess 52a accommodates a film forming material (europium bromide).

Basically, the crucible main body 52 is a so-called boat-shaped vacuum evaporation crucible for use in a resistance heating evaporation source for vacuum evaporation. Like the above-described crucible main body 22, this crucible main body 52 is formed of a high melting point metal, and is adapted to generate heat upon energization of the electrodes 52b, heating and melting the film forming material filling the recess 52a to evaporate the same.

FIG. 6E is a top view of the cover member 54, and FIG. 6F is a front view of the same. As shown in the drawings, the cover member 54 has a configuration in plan view similar to that of the crucible main body 52, and has, at a position corresponding to the recess 52a of the crucible main body 52, a chimney 54a having a slit-like opening extending in the longitudinal direction (=the energizing direction). Further, in the chimney 54a, there is arranged a round bar 54b for preventing the chimney 54a from being crushed, with the round bar being situated at the longitudinal center and held between the inner walls of the chimney 54a.

Like the above-described chimneys 24 formed on the above-described crucibles for heating and evaporating cesium bromide, this chimney 54a serves as the outlet for the vapor of the film forming material and as the filling port for the film forming material. Thus, the crucible 50 is basically arranged such that the open end of the chimney 54a is directed upwards. As in the above-described embodiments, due to the presence of this chimney 54a, it is possible to suitably prevent the film forming material (europium bromide) from leaking to the exterior of the crucible 50 due to bumping. In this embodiment also, the chimney 54a may be omitted.

In an ordinary boat-shaped crucible, the cover member is simply placed thereon.

In contrast, in the crucible 50 of the second aspect of the present invention, the crucible main body 52 and the cover member 54 are firmly connected to each other, and cannot be separated from each other. In the embodiment shown, the crucible main body 52 and the cover member 54 are firmly connected to each other by EB welding at the positions indicated by symbols x in FIG. 6A.

As stated above, in the manufacturing apparatus shown, a phosphor layer is formed on a phosphor sheet by two-source vacuum evaporation using cesium bromide and europium bromide.

Here, in a phosphor layer obtained by multiple source vacuum evaporation, the film forming material constituting the activator component is highly subject to leakage in the molten state, and, when bumping, fluctuation of the liquid surface or the like occurs, it is easily allowed to leak to the exterior through the gap between the crucible main body (the boat-shaped crucible for resistance heating) and the cover member. Thus, the efficiency in the utilization of the film forming materials is rather low. This tendency is particularly conspicuous in the film forming material constituting the activator in the above-mentioned alkali-halide-based stimulable phosphor, in particular, europium bromide used as the film forming material constituting the activator component in the example shown.

In contrast, in the crucible of the second aspect of the present invention, the crucible main body 52 and the cover member 54 are firmly connected to each other, for example, by EB welding. Thus, even if bumping or the like occurs, it is possible to prevent leakage of the film forming material through the gap between them. Thus, according to the present invention, the film forming material utilizing efficiency is improved over the prior art, thus achieving a reduction in production cost.

It is to be noted that, in the crucible of the second aspect of the present invention, the method of firmly connecting the crucible main body 52 and the cover member 54 to each other is not restricted to EB welding as adopted in the embodiment shown. Various methods, including bending, can be adopted as long as they provide a sufficient heat resistance.

While in the crucible 50 of the embodiment shown the cover member 54 is flat, this should not be construed restrictively. For example, it is also possible to suitably adopt a construction in which, as in the case of a cover member 60 shown in FIG. 6G, there is provided a hollow protrusion 60a in the form of a parallel piped with one side open, and in which there is provided thereon a slit-like chimney 60b similar to that in the above embodiment.

In this construction, it is possible to increase the amount of film forming material with which the crucible is filled; when the filling amount is not increased, leakage of the film forming material from the chimney 60b (vapor outlet port) upon bumping can be prevented more suitably.

In the above-described preferred embodiment, the cover member has a slit-like chimney, through which vapor is discharged and the filling of film forming material is effected. However, the crucible of the second aspect of the present invention is not restricted to this. For example, it is also possible to form a large number of through-holes in the region of the cover member corresponding to the recess of the crucible main body and to effect the discharge of vapor and the filling of material through these through-holes.

Further, while in the manufacturing apparatus 10 shown the crucible for the film forming material constituting the activator is composed of a boat-shaped main body and a cover member, the manufacturing apparatus of the present invention is not restricted to this. For example, it is also possible to heat and melt the film forming material constituting the activator by using the cylindrical crucible main body 22 with the chimney 24 as shown, for example, in FIGS. 2A through 2D. In this case, the convection member may be omitted.

In the present invention, the manufacturing apparatus 10 is not restricted to the construction in which it has one phosphor evaporating portion 16 and one activator evaporating portion 18. Various constructions can be adopted as long as they use at least one crucible according to the first aspect of the present invention.

For example, it is possible to adopt a construction for multiple source vacuum evaporation which has two sets or more of the combination of the phosphor evaporating portion 16 and the activator evaporating portion 18. Alternatively, it is also possible to adopt a construction for multiple source vacuum evaporation which has one activator evaporating portion 18 and two or more phosphor evaporating portion 16. Alternatively, it is also possible to realize a unitary vacuum evaporation apparatus which performs vacuum evaporation by using a single film forming material and a crucible according to the first aspect of the present invention.

In the following, the operation of the manufacturing apparatus 10 will be described.

When manufacturing a phosphor sheet, the substrate S is first attached to the lower surface of the turntable 72 of the rotating mechanism 14, with its film forming surface facing downwards. Then, the crucible 20 and the crucible 50 are respectively filled with cesium bromide and europium bromide, and then the vacuum chamber 12 is closed. Subsequently, the vacuum pump is driven to reduce the pressure inside the vacuum chamber 12, and the sheathed heater 76 is driven to heat the substrates from the back side.

When the interior of the vacuum chamber 12 has attained a predetermined vacuum degree, an inert gas, such as argon gas, is introduced to adjust the vacuum degree to a predetermined value if needed. After the vacuum degree adjustment, the turntable 72 is rotated at a predetermined speed by the rotating means 70a, and while doing so, the resistance heating power sources are driven in the phosphor evaporating portion 16 and the activator evaporating portion 18, and the crucible 20 and the crucible 50 are energized to start the heating of cesium bromide and europium bromide, melting and evaporating the two film forming materials and starting the vapor deposition of CsBr:Eu on the substrate S, that is, the formation of the phosphor layer.

After a predetermined film forming time set previously by experiment or the like has elapsed, the heating by the sheathed heater 76, the rotation of the substrate S, and the energization of the crucible 20 and the crucible 50 are stopped. Then, the vacuum chamber 12 is opened, and the substrate S with the phosphor layer formed thereon, that is, the phosphor sheet prepared, is extracted.

The crucible 20 for evaporating cesium bromide constituting the phosphor component has the convection member 26 inside the crucible main body 22, so that bumping of the film forming material, temperature distribution of the molten material, etc. are not generated, making it possible to manufacture a high quality phosphor sheet free from film defect or unevenness in characteristics attributable thereto. In the crucible 50 for evaporating europium bromide constituting the activator component, the crucible main body 52 and the cover member 54 are firmly connected to each other, so that there is no fear of the europium bromide leaking, thus providing high material utilization efficiency.

The embodiments of the vacuum evaporation crucible and the phosphor sheet manufacturing apparatus described in detail above should not be construed restrictively; it goes without saying that various modifications and improvements are possible without departing from the scope of the present invention.

For example, while in the embodiments shown, a stimulable phosphor layer is formed, this should not be construed restrictively; the present invention is also applicable to the film formation of various types of phosphor, such as scintillator.

Further, as shown with reference to the embodiments shown, the vacuum evaporation crucible of the first aspect of the present invention is suitable for the evaporation of a phosphor film forming material (base material) in the film formation of a stimulable phosphor by multiple source vacuum evaporation, whereas the vacuum evaporation crucible of the second aspect of the present invention is suitable for the evaporation of europium bromide. However, the present invention is not restricted to the above uses; it is naturally also applicable to crucibles for evaporating various materials in vacuum evaporation, with the first aspect making the most of the satisfactory convection property for the molten material and the ability to shield any bumped substance, and the second aspect making the most of the material leakage preventing performance.

In the following the present invention will be described in more detail with reference to specific examples thereof.

### EXAMPLE 1

A plate-like substrate S (synthetic quartz substrate) with a size of 450 mm×450 mm was mounted to the turntable 72 (the sheathed heater 76) of the manufacturing apparatus 10. Further, the crucible 20 of the phosphor evaporating portion 16 was filled with cesium bromide (CsBr), and the crucible 50 of the activator evaporating portion 18 was filled with europium bromide (EuBrₓ; x is approximately 2.2). The crucible 20 is a crucible according to the first aspect of the present invention with the convection member 26 as shown in FIGS. 2A through 2D, and the crucible 50 is a crucible according to the second aspect of the present invention as shown in FIGS. 6A through 6G in which the crucible main body 52 and the cover member 54 are connected together by EB welding.

Thereafter, the vacuum chamber 12 was closed and the vacuum pump was driven to start evacuation, and, at the same time, the rotating means 70a was driven to rotate the substrate S at 100 rpm; further, the sheathed heater 76 was driven to heat the substrate S to 120° C.

When the vacuum degree inside the vacuum chamber 12 attained 8×10⁻⁴ Pa, argon gas was introduced into the vacuum chamber 12, and the vacuum degree was adjusted to 0.5 Pa. Next, the resistance heating power sources of the phosphor evaporating portion 16 and the activator evaporating portion 18 were driven to energize the crucible 20 and the crucible 50, and the shutter was opened, forming a phosphor layer of CsBr:Eu on the surface of the substrate S.

The outputs of the resistance heating power sources were adjusted such that the molar concentration ratio of the Eu/Cs in the phosphor layer was 0.003:1 and that the film forming rate was 8 μm/min. This output adjustment was performed based on a film forming experiment conducted beforehand.

When the film thickness of the phosphor layer attained 600 μm, the shutter was closed, the driving of the sheathed heater 76 and the resistance heating power sources was stopped, the rotation of the substrate S was stopped, the vacuum chamber 12 was opened, and the substrate S with the phosphor layer formed thereon, that is, the phosphor plate prepared was extracted.

Visual inspection of the surface of the phosphor sheet prepared showed that the number of surface defects of a size exceeding 100 μm was less than five. Further, upon visual inspection of the interior of the vacuum chamber 12, no leakage of europium bromide was ascertained.

### COMPARATIVE EXAMPLE 1

A phosphor sheet was prepared in the same way as in Example 1 except that the crucible 20 of the phosphor evaporating portion 16 was replaced by an ordinary crucible with no convection member 26, and that the crucible 50 of the activator evaporating portion 18 was replaced by an ordinary crucible in which the crucible main body 52 and the cover member 54 are not connected together by EB welding and in which the cover member 54 is simply placed on the crucible main body 52.

Visual inspection of the surface of the phosphor sheet prepared showed that the number of surface defects of a size exceeding 100 μm substantially exceeded 1,000. Further, upon visual inspection of the interior of the vacuum chamber 12, leakage of europium bromide was ascertained around the crucible of the activator evaporating portion 18.

### EXAMPLE 2

Phosphor sheets were prepared in the same way as in Example 1 except that the crucible 20 of the phosphor evaporating portion 16 was replaced by the crucible 30 shown in FIGS. 3A through 3C, the crucible 36 shown in FIGS. 4A through 4C, and the crucible 40 shown in FIGS. 5A through 5D. Further, a phosphor sheet was prepared in the same way as in Example 1 except that the crucible 50 of the activator evaporating portion 18 was replaced by the crucible with the cover member 60 as shown in FIG. 6G.

In all these examples, the results obtained were the same as in Example 1.

The above results clearly indicate the advantages of the present invention.

1. A crucible for vacuum evaporation comprising:
a crucible main body which accommodates a film forming material and generates heat through energization; and
a convection member which is secured in position inside said crucible main body and forcibly changes a direction of natural convection of said film forming material that is molten.

2. The crucible for vacuum evaporation according to claim 1, wherein said convection member is formed of a material generating the heat through the energization and is electrically connected to said crucible main body.

3. The crucible for vacuum evaporation according to claim 1, wherein said convection member is arranged in contact with an inner surface of said crucible main body and at a position opposed to an outlet port for a vapor of the film forming material.

4. The crucible for vacuum evaporation according to claim 1, wherein said convection member is positioned such that said convection member closes an outlet port for a vapor of the film forming material as seen from above when installed in a vacuum evaporation apparatus.

5. The crucible for vacuum evaporation according to claim 1, wherein said crucible main body has in a part of a hollow container an opening for discharging a vapor of the film forming material that is evaporated, and has a chimney-shaped discharge portion protruding outwardly and surrounding said opening.

6. The crucible for vacuum evaporation according to claim 1, wherein cesium bromide is accommodated and evaporated as said film forming material.

7. A crucible for vacuum evaporation, comprising:
a crucible main body which accommodates a film forming material and generates heat through energization; and
a cover member which closes a film forming material accommodating portion of said crucible main body and is equipped with a vapor outlet port for discharging a vapor of said film forming material that is evaporated,
wherein said crucible main body and said cover member are firmly connected to each other.

8. The crucible for vacuum evaporation according to claim 7, wherein said vapor outlet port is formed as a slit extending in one direction.

9. The crucible for vacuum evaporation according to claim 7, wherein europium bromide is accommodated and evaporated as said film forming material.

10. A phosphor sheet manufacturing apparatus for forming a phosphor layer on a substrate by vacuum evaporation, comprising:
a vacuum chamber;
a substrate retaining mechanism; and
a first crucible for vacuum evaporation comprising:
a first crucible main body which accommodates a film forming material and generates heat through energization; and
a convection member which is secured in position inside said first crucible main body and forcibly changes a direction of natural convection of said film forming material that is molten,
wherein at least one film forming material for forming said phosphor layer is evaporated through resistance heating using said first crucible for vacuum evaporation.

11. The phosphor sheet manufacturing apparatus according to claim 10, wherein said phosphor layer is formed by multiple source vacuum evaporation in which film forming materials for a phosphor component and an activator component are heated and evaporated separately from and independently of each other, said phosphor component being evaporated through the resistance heating using said first crucible for vacuum evaporation.

12. The phosphor sheet manufacturing apparatus according to claim 11, further comprising:
a second crucible for vacuum evaporation, comprising:
a second crucible main body which accommodates a film forming material and generates heat through energization; and
a cover member which closes a film forming material accommodating portion of said second crucible main body and is equipped with a vapor outlet port for discharging a vapor of said film forming material that is evaporated,
wherein said second crucible main body and said cover member are firmly connected to each other, and
wherein the film forming material for the activator component is evaporated through the resistance heating using said second crucible for vacuum evaporation.

13. The phosphor sheet manufacturing apparatus according to claim 12, wherein said first crucible accommodates cesium bromide as the film forming material for the phosphor component, and wherein said second crucible accommodates europium bromide as the film forming material for the activator component.

14. The phosphor sheet manufacturing apparatus according to claim 10, wherein said convection member of said first crucible for vacuum evaporation is formed of a material generating the heat through the energization and is electrically connected to said first crucible main body.

15. The phosphor sheet manufacturing apparatus according to claim 10, wherein said convection member of said first crucible for vacuum evaporation is arranged in contact with an inner surface of said first crucible main body and at a position opposed to an outlet port for a vapor of the film forming material.

16. The phosphor sheet manufacturing apparatus according to claim 10, wherein said convection member of said first crucible for vacuum evaporation is positioned such that said convection member closes an outlet port for a vapor of the film forming material as seen from above when installed at a predetermined position.

17. The phosphor sheet manufacturing apparatus according to claim 10, wherein said first crucible main body of said first crucible for vacuum evaporation has in a part of a hollow container an opening for discharging a vapor of the film forming material that is evaporated, and has a chimney-shaped discharge portion protruding outwardly and surrounding said opening.

18. The phosphor sheet manufacturing apparatus according to claim 12, wherein the vapor outlet port of said second crucible for vacuum evaporation is formed as a slit extending in one direction.
